(19) United States
(12) Patent Application Publication
(10) Pub. No.: US 2025/0006561 A1
(43) Pub. Date: Jan. 2, 2025

(54) STACKED MULTI-GATE DEVICE WITH REDUCED CONTACT RESISTANCE AND METHODS FOR FORMING THE SAME

(71) Applicant: TAIWAN SEMICONDUCTOR MANUFACTURING COMPANY, LTD., Hsinchu (TW)

(72) Inventors: Kuan-Kan HU, Hsinchu (TW); Che Chi SHIH, Taoyuan City (TW); Ku-Feng YANG, Hsinchu County (TW); Szuya LIAO, Hsinchu County (TW)

(73) Assignee: TAIWAN SEMICONDUCTOR MANUFACTURING COMPANY, LTD., Hsinchu (TW)

(21) Appl. No.: 18/344,665

(22) Filed: Jun. 29, 2023

(51) Int. Cl. H01L 21/8238; H01L 21/285; H01L 21/3065; H01L 21/822; H01L 27/092; H01L 29/06; H01L 29/417; H01L 29/423; H01L 29/66; H01L 29/775

(52) U.S. Cl. CPC H01L 21/823814; H01L 21/28518; H01L 21/3065; H01L 21/8221; H01L 21/823807; H01L 21/823871; H01L 27/0922; H01L 29/0673; H01L 29/41733; H01L 29/42392; H01L 29/66439; H01L 29/775

(57) ABSTRACT

Method to form low-contact-resistance contacts to source/drain features is provided. A method of the present disclosure includes receiving a workpiece including an opening that exposes a surface of an n-type source/drain feature and a surface of a p-type source/drain feature, lateral epitaxial structures etching on the n-type source/drain feature creating the offset from the sidewall of the dielectric layer, depositing a silicide layer and the offset between etched epitaxial structures and sidewall of the dielectric layer is eliminated. The lateral epitaxial structures etching includes a reactive-ion etching (RIE) process and an atomic layer etching (ALE) process.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-10D illustrate schematic views of intermediate stages of semiconductor structures in accordance with some embodiments of the present disclosure.

FIG. 11 is a cross-sectional view of a plasma processing apparatus in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. To improve the functional density of the IC structure, a complementary FET (CFET) in which a p-type FET and an n-type FET are vertically stacked has been proposed. A metal silicide can be formed on the source/drain region through a dielectric-defined source/drain opening to improve the silicide-diffusion contact resistance (Rcsd) of the IC structure. However, when forming silicide through source/drain contact openings in the semiconductor process, the space of the source/drain contact opening may become smaller, making it difficult for contact metal to fill the source/drain contact opening. This can result in voids or gaps in the filling metal, which in turn deteriorates the device performance.

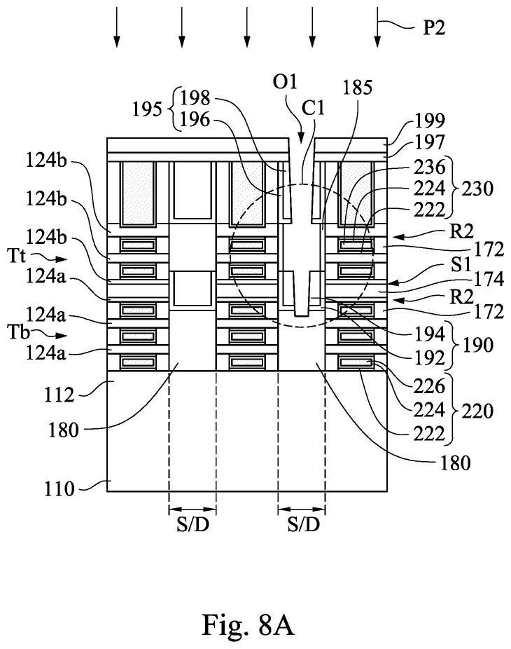

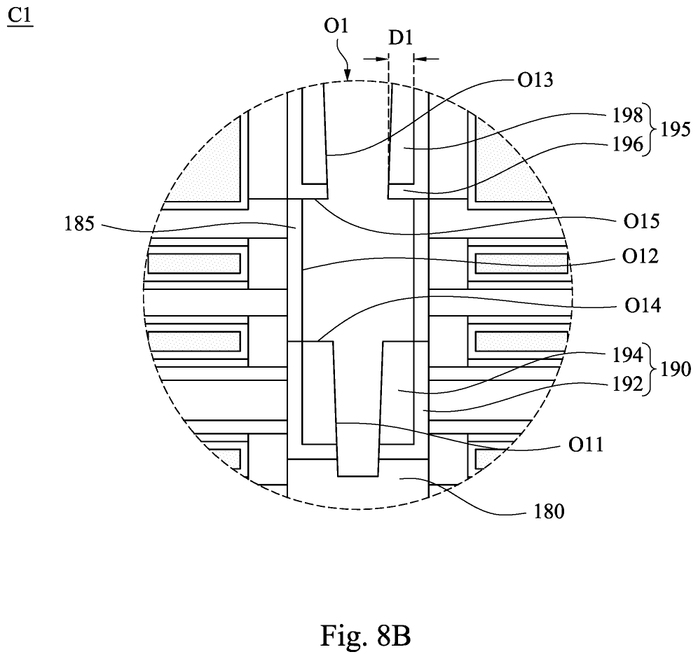

Therefore, the present disclosure in various embodiments provides a method for improving metal filling through the source/drain contact opening in semiconductor process. The method provides an etching process (see FIG. 8A) to lateral trim the source/drain epitaxial structure around the source/drain contact opening, which in turn allows for increasing the space of the source/drain contact opening. By increasing the space of the source/drain contact opening, the silicide layer formed on the source/drain epitaxial structure will not hinder the subsequent metal deposition process, so as to improve metal filling during the subsequent metal deposition, resulting in a voids/gaps-free filling metal, which in turn improves device performance and reliability.

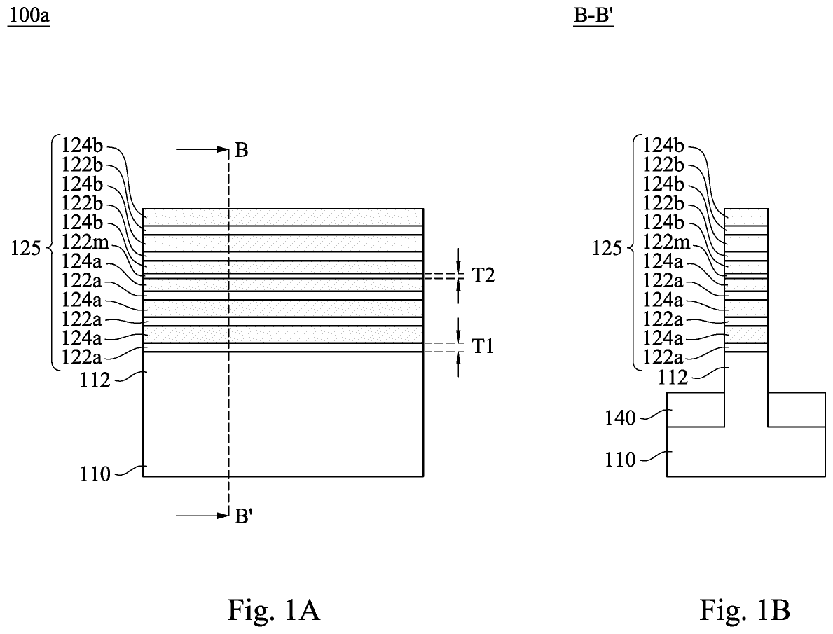

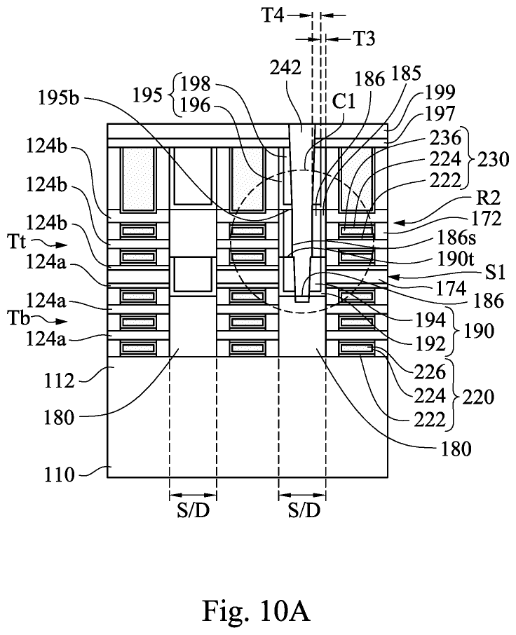

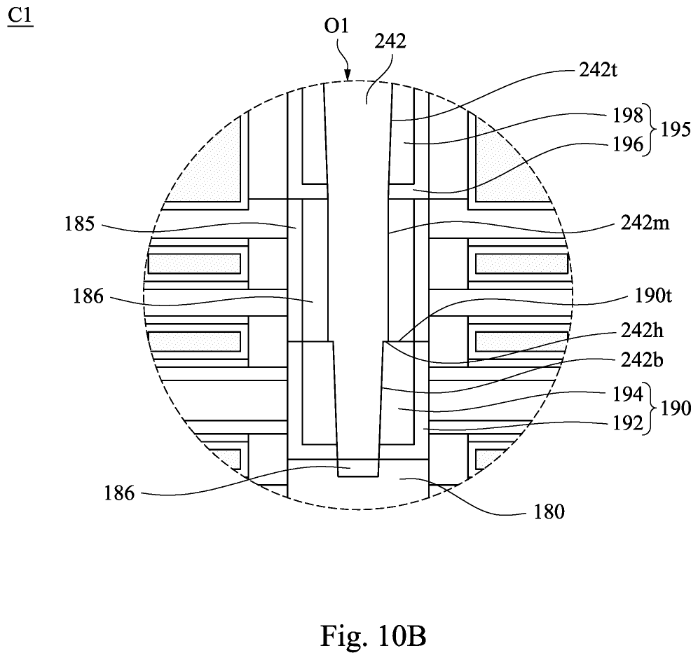

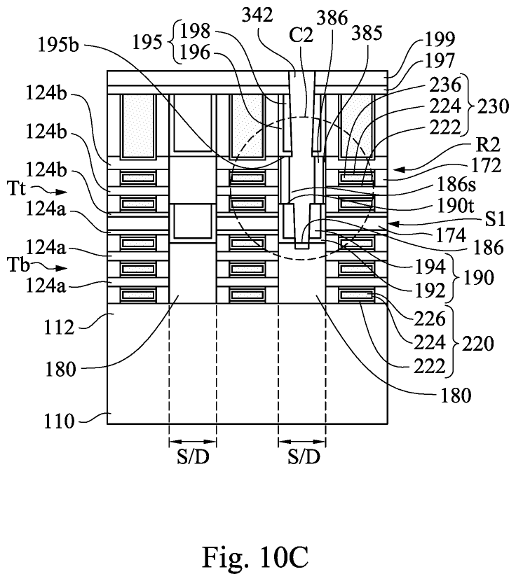

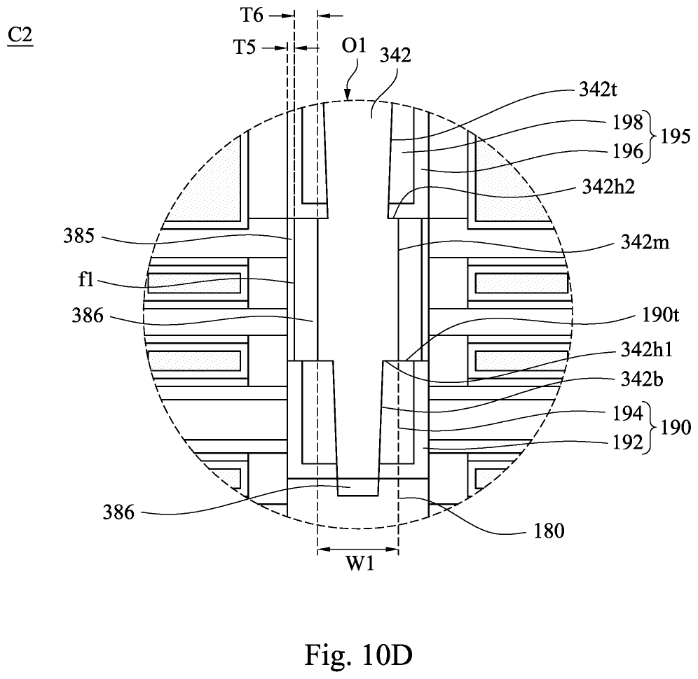

Reference is made to FIGS. 1-10B. FIGS. 1A and 2-8A, 9, and 10A illustrate cross-sectional views of intermediate stages in the formation of a semiconductor structure 100a in accordance with some embodiments. FIG. 1B illustrates a cross-sectional view obtained from the reference cross-section B-B′ in FIG. 1A. FIGS. 8B and 10B are local enlarged views of region C1 in FIGS. 8A and 10A, respectively. Reference is made to FIGS. 1A and 1B. An epitaxial stack is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials.

The epitaxial stack includes epitaxial layers 122a, 122b, 122m of a first composition interposed by epitaxial layers 124a, 124b of a second composition. The first and second compositions can be different. In some embodiments, the epitaxial layers 122a, 122b, 122m may be made of SiGe, and the epitaxial layers 124a, 124b may be made of silicon (Si). However, other embodiments are possible including those that provide for a first composition and a second composition having different etch selectivity.

The epitaxial layers 124a and 124b or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the epitaxial layers 124a and 124b to define a channel or channels of a device is further discussed below. In FIGS. 1A and 1B, the epitaxial layers 124b are disposed above the epitaxial layers 124a. It is noted that three layers of the epitaxial layers 124a and three layers of the epitaxial layers 124b are arranged as illustrated in FIGS. 1A and 1B, which is for illustrative purposes only and not intended to be limiting beyond what is specifically recited in the claims. It can be appreciated that any number of epitaxial layers can be formed in the epitaxial stack; the number of layers depending on the desired number of channels regions for the transistor. In some embodiments, the number of each of the epitaxial layers 124a and 124b can be between 2 and 10.

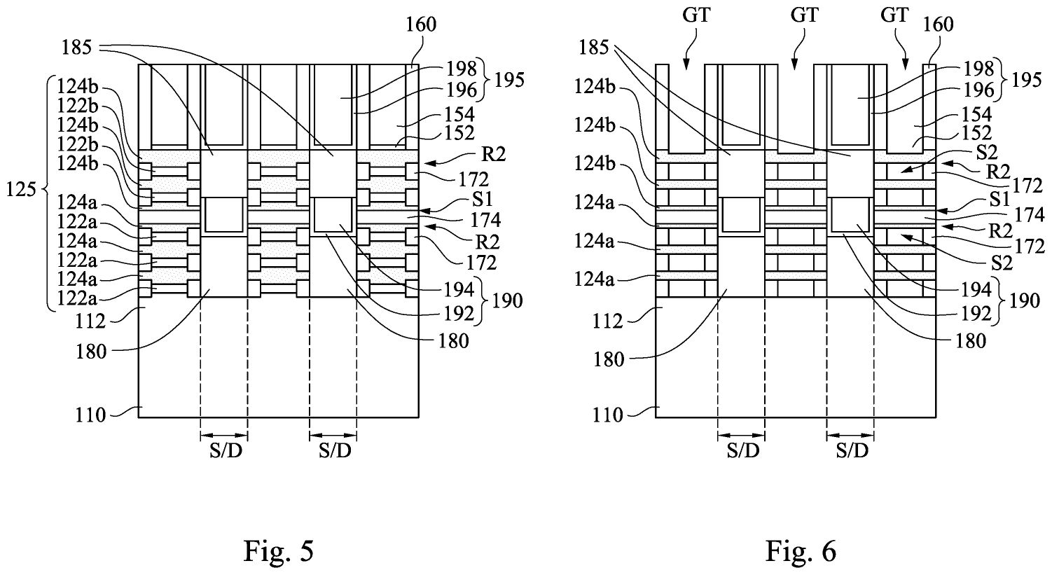

The epitaxial layers 122a are interposed by the epitaxial layers 124a, the epitaxial layers 122b are interposed by the epitaxial layers 124b, and the epitaxial layer 122m is between the epitaxial layers 124a and 124b. In some embodiments, the epitaxial layers 122a and 122b have substantially the same thickness T1 (e.g. vertical dimension), and the epitaxial layer 122m has a thickness T2 (e.g. vertical dimension) less than the thickness T1. In some embodiments, the thickness T2 is determined by the thickness of the isolation structure 190 (see FIG. 5) and is in a range of about 20 nm to about 1000 nm. In some embodiments, the epitaxial layer 122m has a greater germanium atomic concentration than the epitaxial layers 122a and 122b.

As described in more detail below, the epitaxial layers 124a and 124b may serve as channel region(s) for a subsequently-formed semiconductor device and the thickness is chosen based on device performance considerations. The epitaxial layers 122a, 122b, and 122m in channel regions(s) may eventually be removed and serve to define a vertical distance between adjacent channel region(s) for a subsequently-formed multi-gate device and the thickness is chosen based on device performance considerations. Accordingly, the epitaxial layers 122a, 122b, and 122m may also be referred to as sacrificial layers, and epitaxial layers 124a and 124b may also be referred to as channel layers. In some embodiments, the epitaxial layers 124a and 124b can be interchangeably referred to as channel regions or channel patterns.

In some embodiments, the epitaxial layers 122a, 122b, 122m and 124a, 124b include a different material than the substrate 110. As stated above, in at least some examples, the epitaxial layers 122a, 122b, and 122m include an epitaxially grown silicon germanium (SiGe) layer and the epitaxial layers 124a and 124b include an epitaxially grown silicon (Si) layer. Alternatively, in some embodiments, either of the epitaxial layers 122a, 122b, 122m and 124a, 124b may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP. AlInAs, AlGaAs, InGaAs, GaInP, and/or GaInAsP, III-V, or combinations thereof. As discussed, the materials of the epitaxial layers 122a, 122b, 122m and 124a, 124b may be chosen based on providing differing oxidation and/or etching selectivity properties.

In FIGS. 1A and 1B, at least one fin structure 125 extending from the substrate 110 is formed. In various embodiments, the fin structure 125 includes a protruding portion 112 formed from the substrate 110 and portions of each of the epitaxial layers of the epitaxial stack including epitaxial layers 122a, 122b, 122m and 124a, 124b. The fin structure 125 may be fabricated using suitable processes including double-patterning or multi-patterning processes. Next, isolation structures 140 are formed to surround the protruding portion 112. The isolation structures 140 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 140 may also include a dielectric material over the liner oxide, and the dielectric material may be formed using flowable chemical vapor deposition (FCVD), spin-on coating, or the like.

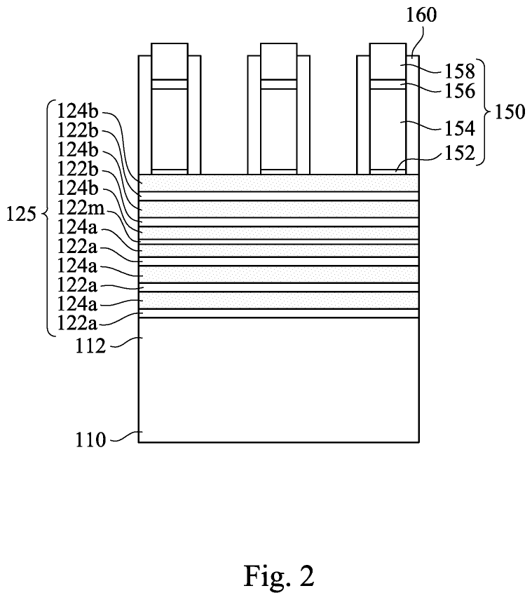

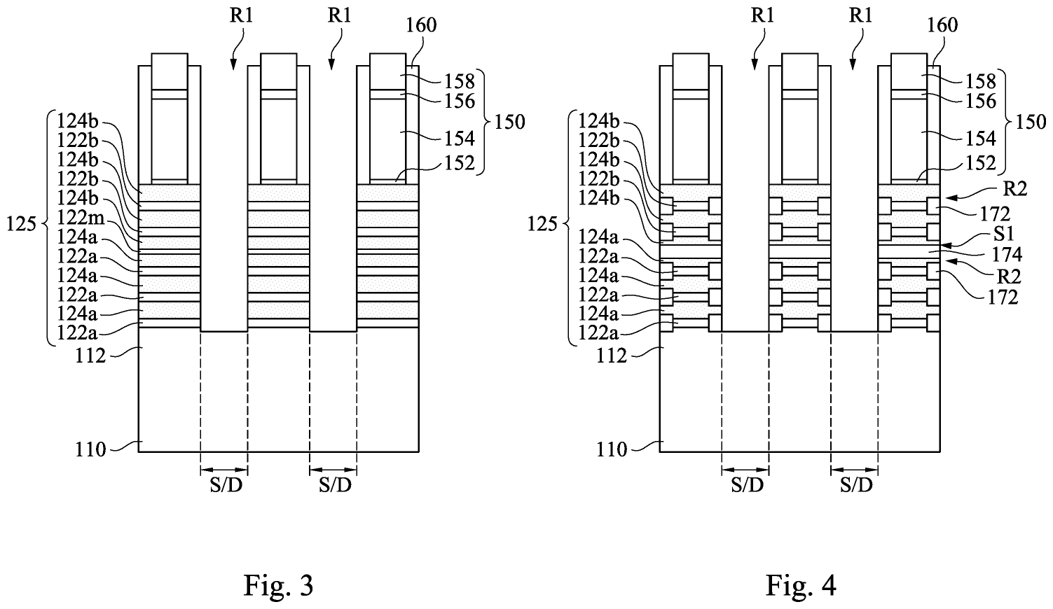

Reference is made to FIG. 2. At least one dummy gate structure 150 is formed over the substrate 110 and is partially disposed over the fin structure 125. The portion of the fin structure 125 underlying the dummy gate structure 150 may be referred to as the channel region. The dummy gate structure 150 may also define source/drain regions S/D (labeled in FIG. 3) of the fin structure 125, for example, the regions of the fin structure 125 adjacent and on opposing sides of the channel region. The dummy gate structure 150 may include a dummy gate dielectric layer 152, a dummy gate electrode layer 154 and a hard mask (e.g., an oxide layer 156 and a nitride layer 158). In some embodiments, the dummy gate structure 150 can be interchangeably referred to a dummy gate, a dummy gate pattern, a dummy gate strip, an isolation structure, or a dielectric gate. In some embodiments, the dummy gate dielectric layer 152 may be made of a dielectric material such as silicon nitride (SiN), silicon oxide (SiO₂), silicon carbo-nitride (SiCN), silicon oxynitride (SiON), silicon oxy-carbo-nitride (SiOCN), or the like. In some embodiments, the dummy gate electrode layer 154 may include polycrystalline-silicon (poly-Si), poly-crystalline silicon-germanium (poly-SiGe), metallic nitrides, metallic silicides, metallic oxides, or metals. In some embodiments, the dummy gate electrode layer 154 includes a metal-containing material such as TiN, TaN, TaC, Co, Ru, Al, combinations thereof, or multi-layers thereof. After formation of the dummy gate structure 150 is completed, gate spacers 160 are formed on sidewalls of the dummy gate structure 150. The gate spacer 160 may include a dielectric material such as silicon oxide, silicon nitride, silicon carbide, silicon oxynitride, SiCN films, silicon oxycarbide, SiOCN films, and/or combinations thereof.

Reference is made to FIG. 3. Exposed portions of the fin structure 125 that extend laterally beyond the gate spacers 160 (e.g., in source/drain regions S/D of the fin structure 125) are etched by using, for example, an anisotropic etching process that uses the dummy gate structure 150 and the gate spacers 160 as an etch mask, resulting in recesses R1 into the fin structure 125. After the anisotropic etching, end surfaces of the epitaxial layers 122a, 122b, 122m, and the epitaxial layers 124a, 124b and respective outermost sidewalls of the gate spacers 160 are substantially coterminous, due to the anisotropic etching.

Reference is made to FIG. 4. Epitaxial layers 122a, 122b, and 122m are laterally or horizontally recessed by using suitable etch techniques, resulting in lateral recesses R2 and a space S1 each vertically between corresponding epitaxial layers 124a and 124b. This operation may be performed by using a selective etching process. By way of example and not limitation, the epitaxial layers 122a, 122b, and 122m are SiGe and the epitaxial layers 124a and 124b are silicon allowing for the selective etching of the epitaxial layers 122a, 122b, and 122m. In some embodiments, the selective dry etching etches SiGe at a faster etch rate than it etches Si. As a result, the epitaxial layers 124a and 124b laterally extend past opposite end surfaces of the epitaxial layers 122a, 122b. In addition, since the epitaxial layer 122m (see FIG. 3) has a greater germanium atomic concentration than the epitaxial layers 122a and 122b, the selective dry etching etches the epitaxial layer 122m at a faster etch rate than it etches the epitaxial layers 122a, 122b, and thus the epitaxial layer 122m can be completely removed while the epitaxial layers 122a, 122b can be only partially removed.

Subsequently, inner dielectric spacers 172 and 174 are filled in the recesses R2 and the space S1, respectively. For example, spacer material layers are formed to fill the recesses R2 and the space S1 left by the lateral etching of the epitaxial layers 122a, 122b, and 122m discussed above. The spacer material layer may be a low-k dielectric material, such as SiO₂, SIN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R2 and the space S1 left by the lateral etching of the epitaxial layers 122a, 122b, and 122m are left. After the trimming process, the remaining portions of the deposited spacer material are denoted as inner dielectric spacers 172 in the recesses R2 and the inner dielectric spacers 174 in the recesses S1, for the sake of simplicity. The inner dielectric spacers 172 and 174 serve to isolate metal gates from source/drain epitaxial structures formed in subsequent processing.

Reference is made to FIG. 5. First source/drain epitaxial structures 180 can be formed on bottoms of the recesses R1 and connected to the epitaxial layers 124a. The first source/drain epitaxial structures 180 may be formed by performing an epitaxial growth process that provides an epitaxial material on the fin structure 125. In some embodiments, the first source/drain epitaxial structures 180 may include Ge, Si, GaAs, AlGaAs, SiGe, GaAsP. SiP, or other suitable material. The first source/drain epitaxial structures 180 may be doped by introducing doping species including: p-type dopants, such as boron or BF₂; n-type dopants, such as phosphorus or arsenic; and/or other suitable dopants including combinations thereof. In some exemplary embodiments, the first source/drain epitaxial structures 180 in a p-type include SiGeB and/or GeSnB. In some embodiments, the first source/drain epitaxial structure 180 can be interchangeably referred to as a source/drain pattern or an epitaxial pattern.

An interlayer dielectric (ILD) layer 194 is formed over the substrate 110. In some embodiments, a contact etch stop layer (CESL) 192 is also formed prior to forming the ILD layer 194. In some examples, the CESL 192 includes a silicon nitride layer, silicon oxide layer, a silicon oxynitride layer, and/or other suitable materials having a different etch selectivity than the ILD layer 194. In some embodiments, the CESL 192 and the ILD layer 194 can be collectively referred to as an isolation structure 190. In some embodiments, the ILD layer 194 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 192. After depositing the ILD layer 194, a planarization process (e.g., CMP process) may be performed to remove excessive materials of the CESL 192 and the ILD layer 194 overlying the dummy gate structures 150. Subsequently, the isolation structures 190 are recessed, such that the upper portions of the recesses R1 may reappear.

Second source/drain epitaxial structures 185 are formed over the epitaxial isolation structure 190. The second source/drain epitaxial structures 185 may be formed by performing an epitaxial growth process that provides an epitaxial material on the epitaxial isolation structure 190. In some embodiments, the second source/drain epitaxial structures 185 may include Ge, Si, GaAs, AlGaAs, SiGe, GaAsP, SiP, or other suitable material. The second source/drain epitaxial structures 185 may be doped by introducing doping species including: p-type dopants, such as boron or BF₂; n-type dopants, such as phosphorus or arsenic; and/or other suitable dopants including combinations thereof. In some exemplary embodiments, the second source/drain epitaxial structures 185 in an n-type transistor include SiP. The first source/drain epitaxial structures 180 and the second source/drain epitaxial structures 185 are made of different materials. For example, the first source/drain epitaxial structures 180 are made of SiGeB and the second source/drain epitaxial structures 185 are made of SiP. In some embodiments, the second source/drain epitaxial structure 185 can be interchangeably referred to as a source/drain pattern or an epitaxial pattern. Each of the epitaxial isolation stacks 190 is between one of the first source/drain epitaxial structures 180 and one of the second source/drain epitaxial structures 185 to electrically isolate the first source/drain epitaxial structure 180 from the second source/drain epitaxial structure 185.

An ILD layer 198 is formed over the substrate 110. In some embodiments, a CESL 196 is also formed prior to forming the ILD layer 198. In some examples, the CESL 196 includes a silicon nitride layer, silicon oxide layer, a silicon oxynitride layer, and/or other suitable materials having a different etch selectivity than the ILD layer 198. In some embodiments, the CESL 196 and the ILD layer 198 can be collectively referred to as an isolation structure 195. In some embodiments, the ILD layer 198 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. After depositing the CESL 196 and the ILD layer 198, a planarization process (e.g., CMP process) may be performed to remove excessive materials of the CESL 196 and the ILD layer 198 overlying the dummy gate structures 150 and further remove hard mask layers 156 and 158 (as shown in FIG. 4), such that the dummy gate electrode layer 154 is exposed.

Reference is made to FIG. 6. The dummy gate dielectric layer 152 and the dummy gate electrode layer 154 are removed first, and then the epitaxial layers (i.e., sacrificial layers) 122a and 122b are removed. The resulting structure is illustrated in FIG. 6. In some embodiments, the dummy gate dielectric layer 152 and/or the dummy gate electrode layer 154 is removed by using a selective etching process (e.g., selective dry etching, selective wet etching, or combinations thereof) that etches the materials in dummy gate dielectric layer 152 and/or dummy gate electrode layer 154 at a faster etch rate than it etches other materials (e.g., the gate spacers 160 and/or the ILD layer 198), thus resulting in a gate trench GT between the gate spacers 160, with the epitaxial layers 122a and 122b exposed in the gate trench GT. Subsequently, the epitaxial layers 122a and 122b in the gate trench GT are removed by using another selective etching process that etches the epitaxial layers 122a and 122b at a faster etch rate than it etches the epitaxial layers 124a and 124b, thus forming spaces S2 between neighboring epitaxial layers (i.e., channel layers) 124a and 124b. This operation is also called a channel release process. In some embodiments, the epitaxial layers 124a and 124b can be interchangeably referred to as nanostructure (nanowires, nanoslabs and nanorings, nanosheet, etc., depending on their geometry).

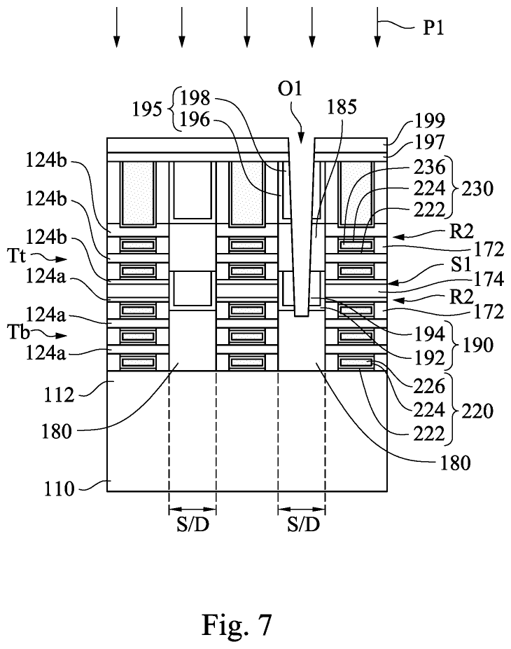

Reference is made to FIG. 7. A (metal) gate structure 220 is formed in the gate trench GT and the spaces S2 to surround each of the epitaxial layers 124a and 124b suspended in the gate trench GT and the spaces S2. In various embodiments, the gate structure 220 includes an interfacial layer 222 formed around the epitaxial layers 124a and 124b, a high-k gate dielectric layer 224 over the interfacial layer 222, and a gate electrode layer 226 formed around the gate dielectric layer and filling a remainder of gate trench GT. In some embodiments, the interfacial layer 222 of the gate dielectric layer may include a dielectric material such as silicon oxide (SiO₂), HfSiO, or silicon oxynitride (SiON). The high-k gate dielectric layer 224 may include dielectric materials having a high dielectric constant (high-k), for example, greater than that of thermal silicon oxide (˜3.9). For example, the high-k dielectric layer 224 of the gate dielectric layer may include hafnium oxide (HfO₂). The gate electrode layer 226 may include a work function metal layer and/or a fill metal formed around the work function metal layer. For an n-type FinFET, the work function metal layer may include one or more n-type work function metals. On the other hand, for a p-type FinFET, the work function metal layer may include one or more p-type work function metals. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC. TaSiN, TaCN, TiAl, TiAlN, or other suitable materials.

After the formation of the gate structure 220, the fill metal is etched back by using an etching process, and top portions of the work function metal layer are exposed. Next, the top portions of the work function metal layer are removed by using an etching process, and top portions of the gate dielectric layer 224 are exposed, such that the upper portions of the gate trenches GT may reappear. In some embodiments, the gate structure 220 can be interchangeably referred to a metal gate, a gate pattern, or a gate strip. A gate electrode layer 236 is deposited in the gate trench GT and over the gate electrode layer 226. Therefore, a gate structure 230 including the interfacial layer 222, the high-k dielectric layer 224, the gate electrode layer 236 is formed within the remainder of the spaces S2. As such, the semiconductor device 100a is formed. In some embodiments, the gate structure 230 can be interchangeably referred to a metal gate, a gate pattern, or a gate strip. In some embodiments, the gate electrode layer 236 may include a work function metal layer and/or a fill metal formed around the work function metal layer. For an n-type FinFET, the work function metal layer may include one or more n-type work function metals. On the other hand, for a p-type FinFET, the work function metal layer may include one or more p-type work function metals. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

The semiconductor device 100a includes a bottom-tier transistor Tb and a top-tier transistor Tt. The top-tier transistor Tt is over the bottom-tier transistor Tb. The bottom-tier transistor Tb includes the channel layers 124a, the first source/drain epitaxial structures 180 on opposite sides of the channel layers 124a and connected to the channel layers 124a, and the gate structure 220 wrapping around the channel layers 124a. The top-tier transistor Tt includes the channel layers 124b, the second source/drain epitaxial structures 185 on opposite sides of the channel layers 124b and connected to the channel layers 124b, and a (metal) gate structure 230 wrapping around the channel layers 124b. In some embodiments, the bottom-tier transistor Tb is a p-type transistor, and the top-tier transistor Tt is an n-type transistor. In some other embodiments, the bottom-tier transistor Tb is an n-type transistor, and the top-tier transistor Tt is a p-type transistor. An ILD layer 199 is formed over the substrate 110. In some embodiments, a CESL 197 is also formed prior to forming the ILD layer 197. In some examples, the CESL 197 includes a silicon nitride layer, silicon oxide layer, a silicon oxynitride layer, and/or other suitable materials having a different etch selectivity than the ILD layer 199. In some embodiments, the ILD layer 199 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL.

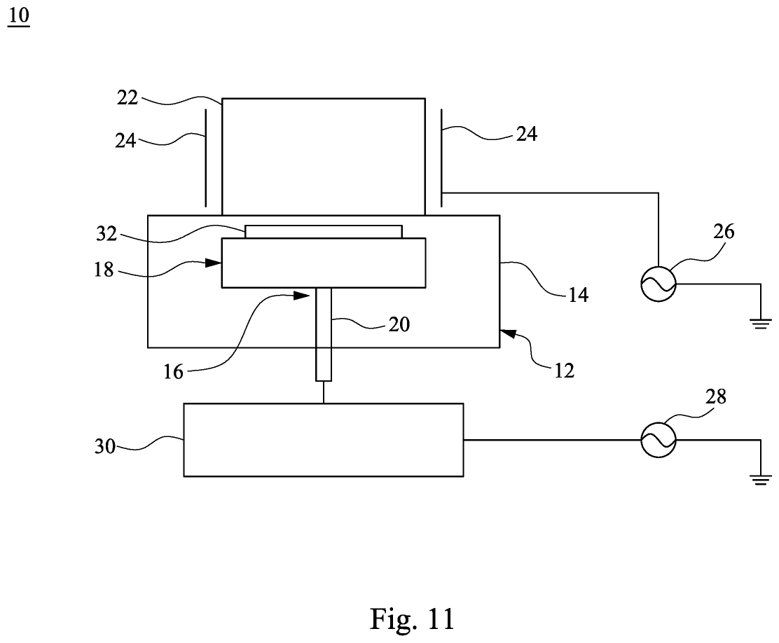

Subsequently, one or more etching process P1 may be performed by using a plasma processing apparatus 10 as shown in FIG. 11. The etching process P1 can be performed to sequentially etch through the ILD layer 199, the CESL 197, the ILD layer 198, the CESL 196, second source/drain epitaxial structure 185, the ILD layer 194, and the CESL 192 down to the first source/drain epitaxial structure 180 to form the source/drain contact opening O1, such that the first source/drain epitaxial structure 180 can be exposed from the source/drain contact opening O1. In some embodiments, the etching process P1 would consume the first source/drain epitaxial structure 180, and thus the first source/drain epitaxial structure 180 may be damaged as shown in FIG. 7.

In some embodiments, the etching process P1 is an anisotropic dry etching process (e.g., a reactive-ion etching (RIE) process or an atomic layer etching (ALE) process), and other forms of plasma processing. By way of example and not limitation, a dry etching process may implement an oxygen-containing gas, a fluorine-containing gas (e.g., CF₄, SF₆, CH₂F₂, CHF₃, CH₃F and/or C₄F₈), a chlorine-containing gas (e.g., Cl₂ and/or BCl₃), a bromine-containing gas (e.g., HBr), an iodine-containing gas, other suitable gases and/or plasmas, and/or combinations thereof. In some embodiments, the etching process P1 may be anisotropic.

This is described in greater detail for an embodiment with reference to FIG. 7, The etching process P1 can include adjusting the relative power levels of top and bottom bias powers providing by the RF source power supply 26 (see FIG. 11) and the RF power supply 28 (see FIG. 11) of the plasma processing apparatus 10, and the top and bottom bias powers can be applied to the substrate 110 during the etching process P1 to achieve the desired etching profile. By controlling the top and bottom bias powers, the etching process P1 allows for the selective etching on the substrate 110, resulting in anisotropic etching behavior. The apparatus used in the etching process P1 may include a plasma processing chamber 12 (see FIG. 11) with a pedestal assembly 18 (see FIG. 11) configured to provide independent control of the top and bottom bias powers. In the etching process P1, plasma is used to remove material from a substrate 110 by bombarding it with ions or radicals. The etching process P1 can be anisotropic, where material is removed more in one direction (e.g., vertical direction) than in others. One important factor that can affect the anisotropic or isotropic etching characteristics of the etching process P1 is the relative power levels of the top and bottom bias powers applied to the substrate 110 during the etching process P1. The top bias power is applied to an upper electrode above the substrate 110, while the bottom bias power is applied to a lower electrode beneath the substrate 110. For example, if the bottom bias power is increased relative to the top bias power, the etching behavior will become more anisotropic, with material being removed more in the vertical direction than in the lateral direction.

In semiconductor device fabrication, it can use silicide layers on source/drain regions to reduce resistance and improve device performance. However, when forming silicide through source/drain contact opening in the semiconductor process, the space of the source/drain contact opening may become smaller, making it difficult for contact metal to fill the source/drain contact opening. This can result in voids or gaps in the filling metal, which in turn deteriorates the device performance.

To address this issue, the present disclosure provides a method for improving metal filling through the source/drain contact opening in semiconductor process. The method provides an etching process (see FIG. 14A) to lateral trim the source/drain epitaxial structure around the source/drain contact opening, which in turn allows for increasing the space of the source/drain contact opening. By increasing the space of the source/drain contact opening, the silicide layer formed on the source/drain epitaxial structure will not hinder the subsequent metal deposition process, so as to improve metal filling during the subsequent metal deposition, resulting in a voids/gaps-free filling metal, which in turn improves device performance and reliability.

FIG. 11 illustrates a cross-sectional view of the exemplary plasma processing apparatus 10 in some embodiments of the present disclosure. The etching process P1 can be provided by the ICP plasma source 26 with turning on the RF power source 28. In some embodiments, the plasma processing apparatus 10 may contain an inductively-coupled plasma (ICP) as a plasma source and a RF power supply as a bias power source. As shown in FIG. 11, the plasma processing apparatus 10 includes a chamber 12 having a typically grounded chamber wall 14. The chamber 12 is closed by a removable lid or a cover 22 and contains a pedestal assembly 18 which can typically be raised and lowered on a shaft 20 by actuation of a pedestal lift assembly 16. An inductively-coupled plasma coil 24 surrounds the lid 22 and is connected to an RF source power supply 26 providing the top bias power. The pedestal assembly 18 is connected, through an RF match network 30 which matches impedences, to an RF power supply 28 providing the bottom bias power. During operation of the plasma processing apparatus 10, the pedestal assembly 18 supports a wafer 32 in the chamber 12. A plasma-generating source gas, such as argon, is introduced into the plasma processing apparatus 10 by a gas supply (not shown). Volatile reaction products and unreacted plasma species are removed from the plasma processing apparatus 10 by a gas removal mechanism (not shown). Source power such as a high voltage signal, provided by the RF source power supply 26, is applied to the inductively-coupled plasma coil 24 to ignite and sustain plasma in the plasma processing apparatus 10. Ignition of the plasma in the plasma processing apparatus 10 is accomplished primarily by electrostatic coupling of the inductively-coupled plasma coil 24 with the source gas, due to the large-magnitude voltage applied to the inductively-coupled plasma coil 24 and the resulting electric fields produced in the plasma processing apparatus 10. Once ignited, the plasma is sustained by electromagnetic induction effects associated with time-varying magnetic fields produced by the alternating currents applied to the inductively-coupled plasma coil 24. Through the RF power supply 28, the pedestal assembly 18 is typically electrically biased to provide to the wafer 32 ion energies that are independent of the RF voltage applied to the chamber 10 through the inductively-coupled plasma coil 24 and RF source power supply 26. This facilitates more precise control over the energies of the etchant ions that bombard the surface of the wafer 32.

Reference is made to FIGS. 8A and 8B. One or more etching process P2 may be performed to laterally trim the second source/drain epitaxial structure 185 by using, such as the plasma processing apparatus 10 as shown in FIG. 11, such that a middle portion of the source/drain contact opening O1 can be enlarge. In some embodiments, the etching process P2 can be interchangeably referred to as a trimming process. The second source/drain epitaxial structure 185 is laterally or horizontally recessed in a distance D1 (see FIG. 8B) about 1 to 5 nm (e.g. about 1, 2, 3, 4, or 5 nm), by using the etching process P2, resulting in a lateral recess. In other words, the source/drain contact opening O1 can be laterally expanded.

Therefore, after the etching process P2 is performed, the source/drain contact opening O1 can having a stepped sidewall (e.g., two step shape). The stepped sidewall can have a lower sidewall O11, a middle sidewall O12, and an upper sidewall O13, in which sidewalls of the isolation structures 190 and 195 serve as the lower and upper sidewalls O11 and O13, and a sidewall of the second source/drain epitaxial structure serves as the middle sidewall O12. The middle sidewall O12 of the source/drain contact opening O1 is laterally set back from the lower sidewall O11 and the upper sidewall O13. In addition, the top surface of the isolation structure 190 serving as a horizontal surface O14 connects the lower sidewall O11 to the middle sidewall O12, and the bottom surface of the isolation structure 195 serving as a horizontal surface O15 connects the upper sidewall O13 to the middle sidewall O12. In other words, the top surface of the isolation structure 190 and the bottom surface of the isolation structure 195 can be exposed from the source/drain contact opening O1. The sidewall of the second source/drain epitaxial structure 185 is etched to create an offset from the sidewalls of the isolation structures 190 and 195 within the source/drain contact opening O1, in which “offset” refers to the difference in the positions of the sidewalls of the second source/drain epitaxial structure 185 and the isolation structures 190 and 195 within the source/drain contact opening O1. Stated differently. The term “offset” in this context means that the sidewall of the second source/drain epitaxial structure 185 is not aligned with the sidewalls of the isolation structures 190 and 195 but is shifted to a certain extent, creating a desired separation.

In some embodiments, the etching process P2 is an isotropic dry etching process (e.g., a reactive-ion etching (RIE) process or an atomic layer etching (ALE) process), and may employ a different etchant than that used in the etching process P1. In some embodiments, the etchant used in the etching process P2 is substantially the same as the etching process P1. In some embodiments, the etching selectivity, which is the ratio of the etching rate of the second source/drain epitaxial structure 185 to the isolation structures 190 and 195 is greater than about 5, such as about 6, 7, 8, 9, or 10, during the etching process P2.

By way of example and not limitation, a dry etching process may implement an etchant including an oxygen-containing gas, a fluorine-containing gas (e.g., CF₄, SF₆, CH₂F₂, CHF₃, CH₃F and/or C₄F₈), a chlorine-containing gas (e.g., Cl₂ and/or BCl₃), a bromine-containing gas (e.g., HBr), an iodine-containing gas, other suitable gases and/or plasmas, and/or combinations thereof. In some embodiments, the oxygen gas of the etching process P2 can be flowed into the process chamber accommodating the substrate 110 at a lower flow rate than the etching process P1. In some embodiments, the etchant used in the etching process P2 may be oxygen-free.

This is described in greater detail for an embodiment with reference to FIG. 8A, the etching process P2 can include adjusting the relative power levels of top and bottom bias powers providing by the RF source power supply 26 (see FIG. 11) and the RF power supply 28 (see FIG. 11) of the plasma processing apparatus 10, and the top and bottom bias powers can be applied to the substrate 110 during the etching process P2 to achieve the desired etching profile. By controlling the top and bottom bias powers, the etching process P2 allows for the selective etching on the substrate 110, resulting in isotropic etching behavior. The apparatus used in the etching process P2 may include a plasma processing chamber 12 (see FIG. 11) with a pedestal assembly 18 (see FIG. 11) configured to provide independent control of the top and bottom bias powers. In the etching process P2, plasma is used to remove material from a substrate 110 by bombarding it with ions or radicals. The etching process P2 can be either isotropic, where material is removed uniformly in all directions. One important factor that can affect the anisotropic or isotropic etching characteristics of the etching process P2 is the relative power levels of the top and bottom bias powers applied to the substrate 110 during the etching process P2. The top bias power is applied to an upper electrode above the substrate 110, while the bottom bias power is applied to a lower electrode beneath the substrate 110. If the bottom bias power is decreased relative to the top bias power, the etching behavior will become more isotropic, with material being removed more uniformly in all directions. In some embodiments, the bottom bias power may be less than about 50 W/cm², such as about 50, 40, 30, 20, 10, or 5 W/cm². If the bias power is higher than about 50 W/cm², the plasma might result in an unwanted etching profile on the second source/drain epitaxial structure 185 and result in a damage to the source/drain epitaxial structure 180. In some embodiments, the etching process P2 may have a lower bottom bias power than the etching process P1. In some embodiments, the bottom bias power can be zero. That is, the etching process P2 can be provided by the ICP plasma source 26 (see FIG. 11) without turning on the RF power source 28.

In some embodiments, the etching processes P1 and P2 can be in-situ performed. As used herein, the term “in-situ” is used to describe processes that are performed while a device or substrate remains within a processing system (e.g., including a load lock chamber, transfer chamber, processing chamber, or any other fluidly coupled chamber), and where for example, the processing system allows the substrate to remain under vacuum conditions. As such, the term “in-situ” may also generally be used to refer to processes in which the device or substrate being processed is not exposed to an external environment (e.g., external to the processing system). In some embodiments, the etching processes P1 and P2 can be ex-situ performed.

In some embodiments, the etching process P2 can result in position-dependent etching rates, meaning that the etching rate at a higher position on the substrate may be greater than the etching rate at a lower position, such that the etching process P2 would not significantly consume the first source/drain epitaxial structure 180 in a lower position than the second source/drain epitaxial structure 180. In some embodiments, the substrate 110 is exposed to a gas mixture that includes a reactive species, and controlling the concentration of the reactive species at different positions on the substrate 110 to achieve the desired etching rates. For example, the concentration of the reactive species can be higher at the top of the substrate 110 and lower at the bottom, resulting in a greater etching rate at the top than at the bottom.

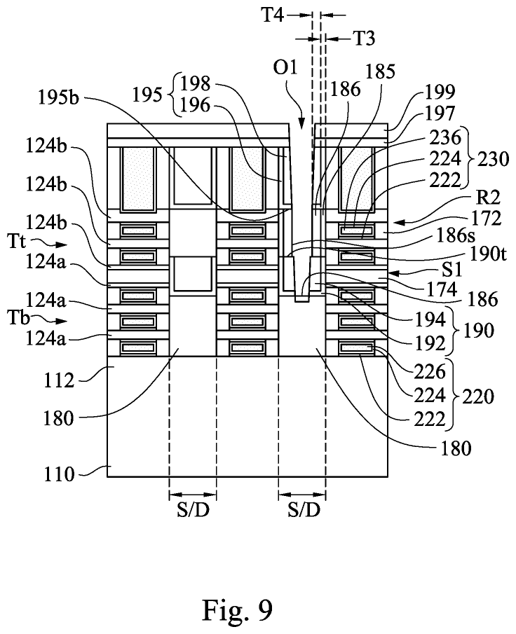

Reference is made to FIG. 9. Before the source/drain contact 242 (see FIGS. 10A and 10B) is formed, metal silicide layers 186 may be selectively formed on the first and second source/drain epitaxial structures 180 and 185 through the source/drain contact opening O1 by a metal silicidation process. The metal silicidation process is to make a reaction between metal and silicon (or polycrystalline silicon). Regarding the metal silicidation process, a first rapid thermal annealing (RTA) process may be performed in, for example, Ar, He, N2 or other inert atmosphere at a first temperature, such as lower than 200˜300 C, to convert the deposited metal layer into metal silicide. This is followed by an etching process to remove the unreacted metal layer from the metal silicide. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400˜500° C., thereby forming the metal silicide layer 186 with low resistance. In some embodiments, the metal silicide layer 186 may be made of n-silicide. In some embodiments, the metal silicide layer 186 may include titanium silicide (TiSi), nickel silicide (NiSi), cobalt silicide (CoSi), Ni—Pt, or combinations thereof. The metal silicide layers 186 formed on the first and second source/drain epitaxial structures 180 and 185 can provide a planar silicide surface area without compromising Rcsd.

As shown in FIG. 9, because the top surface of the isolation structure 190 and the bottom surface of the isolation structure 195 can be exposed from the source/drain contact opening O1, the metal silicide layer 186 formed on the second source/drain epitaxial structure 185 can be in contact with the top surface 190t of the isolation structure 190 and the bottom surface 195b of the isolation structure 195. In some embodiments, the metal silicide layer 186 may have a sidewall 186s coterminous with a sidewall of the isolation structure 190 and/or a sidewall of the isolation structure 195. In some embodiments, the metal silicide layer 186 may have a sidewall 186s set back from a sidewall of the isolation structure 190 and/or a sidewall of the isolation structure 195. In some embodiments, the metal silicide layer 186 may have a lateral dimension T4 (e.g. thickness) greater than a lateral dimension T3 (e.g. thickness) of the second source/drain epitaxial structure 185 from the cross-sectional view. In some embodiments, the metal silicide layer 186 may have a same lateral dimension as the second source/drain epitaxial structure 185 from the cross-sectional view. In some embodiments, the metal silicide layers 186 can also be formed on the sidewalls of the isolation structures 190 and 195.

Reference is made to FIGS. 10A and 10B. A source/drain contact 242 is formed in a remainder of the source/drain contact opening O1 and on the metal silicide layers 186. In some embodiments, the source/drain contact 242 can be interchangeably referred to as a metal-like defined (MD) layer. In greater detail, a conductive material may be formed by using a metallization process to fill the source/drain contact opening O1. Subsequently, the excess portions of the conductive material are removed, either through etching, chemical mechanical polishing (CMP), or the like, forming the upper surface of the metal-filled opening substantially coplanar with a top surface of the ILD layer 198. The remaining portions of the conductive material in the source/drain contact opening O1 forms the source/drain contact 242. The conductive material may include a low resistivity conductor material selected from the group of conductor materials including, but not limited to, tungsten and tungsten-based alloy. Alternatively, the conductive material may include various materials, such as cobalt, copper, ruthenium, aluminum, gold, silver, another suitable conductive material, or combinations thereof. As shown in FIG. 10B, the source/drain contact 242 can be a stepped sidewall structure having a lower sidewall 242b, a middle sidewall 242m, and an upper sidewall 242t. The lower sidewall 242b is lateral set back from the middle sidewall 242m. The source/drain contact 242 can further have a horizontal surface 242h connecting the lower sidewall 242b to the middle sidewall 242m. The horizontal surface 242h can be in contact with the top surface 190t of the isolation structure 190.

Reference is made to FIGS. 10C and 10D. FIG. 10C illustrates a schematic cross-sectional view of a semiconductor structure corresponding to FIG. 10A. FIG. 10D is a local enlarged view of region C2 in FIG. 10C. While FIGS. 10C and 10D shows an embodiment of a semiconductor structure with a source/drain epitaxial structure 385 having a less lateral dimension (e.g. thickness) and a source/drain contact 342 having a different cross-sectional profile than the semiconductor structure in FIGS. 1A-10B. In addition, the present disclosure may repeat reference numerals and/or letters in the various examples. This repetition is for the purpose of simplicity and clarity and does not in itself dictate a relationship between the various embodiments and/or configurations discussed.

As shown in FIGS. 10C and 10D, the source/drain epitaxial structure 385 may have a lateral dimension T5 (e.g., thickness) than the lateral dimension T3 of the source/drain epitaxial structure 185 (see FIG. 9). In some embodiments, the lateral dimension T5 of the source/drain epitaxial structure 385 may be less than a lateral dimension T6 (e.g., thickness) of the metal silicide layer 386 formed on the source/drain epitaxial structure 385. In some embodiments, the metal silicide layer 386 and the source/drain contact 342 can have an interface f1 set back from a sidewall of the isolation structure 190 and/or a sidewall of the isolation structure 195. The source/drain contact 342 can have a stepped sidewall (e.g., two step shape). The stepped sidewall can have a lower sidewall 342b, a middle sidewall 342m, and an upper sidewall 342t. The lower sidewall 342b and the upper sidewall 342t of the source/drain contact 342 are laterally set back from the middle sidewall 342m. In other words, the middle portion of the source/drain contact 342 has a wider width W1 than the lower portion and the upper portion of the source/drain contact 342. In addition, the source/drain contact 342 further have a horizontal surface 342h1 connects the lower sidewall 342b to the middle sidewall 342m, and a horizontal surface 342h2 connects the upper sidewall 342t to the middle sidewall 342m. The horizontal surface 342h1 can be in contact with the top surface of the isolation structure 190, and the horizontal surface 342h2 can be in contact with the bottom surface of the isolation structure 195.

In some embodiments, material and manufacturing method for forming the source/drain epitaxial structure 385, the metal silicide layer 386, and the source/drain contact 342 are substantially the same as the material and manufacturing method for forming the source/drain epitaxial structure 185, the metal silicide layer 186, and the source/drain contact 242 described in foregoing descriptions and thus are not repeated herein for the sake of clarity.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method for improving source/drain contact metal filling through the source/drain contact opening in semiconductor process. The method provides an etching process (see FIG. 8A) to lateral trim the source/drain epitaxial structure around the source/drain contact opening, which in turn allows for increasing the space of the source/drain contact opening. By increasing the space of the source/drain contact opening, the silicide layer formed on the source/drain epitaxial structure will not hinder the subsequent metal deposition process, so as to improve metal filling during the subsequent metal deposition, resulting in a voids/gaps-free filling metal, which in turn improves device performance and reliability.

In some embodiments, a method includes forming a bottom-tier transistor comprising a first channel layer, a first gate structure around the first channel layer, and a plurality of first source/drain regions on opposite sides of the first channel layer; forming a dielectric layer over the first source/drain regions of the bottom-tier transistor; forming a top-tier transistor over the bottom-tier transistor, the top-tier transistor comprising a second channel layer, a second gate structure around the second channel layer, and a plurality of second source/drain regions on opposite sides of the second channel layer and over the dielectric layer; etching a one of the second source/drain regions of the top-tier transistor and the dielectric layer to form an opening exposing one of the first source/drain regions of the bottom-tier transistor; after forming the opening, laterally trimming the one of the second source/drain regions of the top-tier transistor through the opening; forming a metal silicide on the trimmed one of the second source/drain regions; forming a source/drain contact in the opening. In some embodiments, laterally trimming the one of the second source/drain regions is performed by using a fluorine-based enchant or a chlorine-based enchant. In some embodiments, after the laterally trimming, the one of the second source/drain regions has a sidewall offset from a sidewall of the dielectric layer in the opening by a non-zero distance. In some embodiments, the metal silicide is in contact with a top surface of the dielectric layer exposed from the trimmed one of the second source/drain regions. In some embodiments, laterally trimming the one of the second source/drain regions is performed by an isotropic dry etching process. In some embodiments, laterally trimming the one of the second source/drain regions is performed by a dry etching process with a bottom bias power lower than a bottom bias power used in etching the one of the second source/drain regions. In some embodiments, laterally trimming the one of the second source/drain regions is performed by a dry etching process with a bottom bias power less than about 50 W/cm². In some embodiments, laterally trimming the one of the second source/drain regions is performed by introducing an oxygen precursor at a flow rate lower than a flow rate of an oxygen precursor used in etching the one of the second source/drain regions. In some embodiments, laterally trimming the one of the second source/drain regions is performed by introducing an oxygen-free precursor on the one of the second source/drain regions. In some embodiments, etching the one of the second source/drain regions and laterally trimming the one of the second source/drain regions are in-situ performed.

In some embodiments, a method includes forming a first semiconductive nanostructure, and a second semiconductive nanostructure vertically arranged with respect to the first semiconductive nanostructure; forming a plurality of first epitaxial structures on opposite sides of the first semiconductive nanostructure, and a plurality of second epitaxial structures on opposite sides of the second semiconductive nanostructure; forming a dielectric layer over the second epitaxial structures; forming a first gate wrapping around the first semiconductive nanostructure, and a second gate wrapping around the second semiconductive nanostructure; etching through the dielectric layer and one of the second epitaxial structures to form an opening exposing the one of the first epitaxial structures; etching a sidewall of the one of the second epitaxial structures to create an offset from a sidewall of the dielectric layer within the opening; after creating the offset from the sidewall of the dielectric layer within the opening, forming a silicide on the sidewall of the one of the second epitaxial structures; filling a contact material in the opening. In some embodiments, the silicide is in contact with a bottom surface of the dielectric layer exposed from the one of the second epitaxial structures. In some embodiments, the contact material is in contact with a bottom surface of the dielectric layer exposed from the one of the second epitaxial structures. In some embodiments, creating the offset from the sidewall of the dielectric layer within the opening is performed ex-situ with etching through the dielectric layer and the one of the second epitaxial structures. In some embodiments, creating the offset from the sidewall of the dielectric layer within the opening is performed by a dry etching process without a bias power.

In some embodiments, a semiconductor structure includes a first transistor, a second transistor, and a source/drain contact. The first transistor includes first semiconductor sheets, a first gate structure surrounding each of the first semiconductor sheets, and first source/drain structures on either side of each of the first semiconductor sheets. The second transistor is over the first transistor and includes second semiconductor sheets, a second gate structure surrounding each of the second semiconductor sheets, and second source/drain structures on either side of each of the second semiconductor sheets. The source/drain contact extends through one of the second source/drain structures of the second transistor to one of the first source/drain structures of the first transistor. The source/drain contact includes a first profile having a first sidewall and a second sidewall opposing the first sidewall, and a second profile over the first profile and having a third sidewall and a fourth sidewall opposing the third sidewall. At a boundary of the first profile and the second profile, a width between the third sidewall and the fourth sidewall is greater than a width between the first sidewall and the second sidewall by a non-zero offset value. In some embodiments, semiconductor structure further includes a silicide layer interfacing the second profile of the source/drain contact. In some embodiments, the silicide layer is spaced apart from the first profile of the source/drain contact. In some embodiments, the source/drain contact further comprises a third profile over the second profile and having a fifth sidewall and a sixth sidewall opposing the fifth sidewall, and wherein at a boundary of the third profile and the second profile, a width between the fifth sidewall and the sixth sidewall is less than the width between the third sidewall and the fourth sidewall. In some embodiments, along a vertical direction, a variation in the width between the first sidewall and the second sidewall of the first profile is different from a variation in the width between the third sidewall and the fourth sidewall of the second profile.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a bottom-tier transistor comprising a first channel layer, a first gate structure around the first channel layer, and a plurality of first source/drain regions on opposite sides of the first channel layer;
forming a dielectric layer over the first source/drain regions of the bottom-tier transistor;
forming a top-tier transistor over the bottom-tier transistor, the top-tier transistor comprising a second channel layer, a second gate structure around the second channel layer, and a plurality of second source/drain regions on opposite sides of the second channel layer and over the dielectric layer;
etching a one of the second source/drain regions of the top-tier transistor and the dielectric layer to form an opening exposing one of the first source/drain regions of the bottom-tier transistor;
after forming the opening, laterally trimming the one of the second source/drain regions of the top-tier transistor through the opening;
forming a metal silicide on the trimmed one of the second source/drain regions; and
forming a source/drain contact in the opening.

2. The method of claim 1, wherein laterally trimming the one of the second source/drain regions is performed by using a fluorine-based enchant or a chlorine-based enchant.

3. The method of claim 1, wherein after the laterally trimming, the one of the second source/drain regions has a sidewall offset from a sidewall of the dielectric layer in the opening by a non-zero distance.

4. The method of claim 1, wherein the metal silicide is in contact with a top surface of the dielectric layer exposed from the trimmed one of the second source/drain regions.

5. The method of claim 1, wherein laterally trimming the one of the second source/drain regions is performed by an isotropic dry etching process.

6. The method of claim 1, wherein laterally trimming the one of the second source/drain regions is performed by a dry etching process with a bottom bias power lower than a bottom bias power used in etching the one of the second source/drain regions.

7. The method of claim 1, wherein laterally trimming the one of the second source/drain regions is performed by a dry etching process with a bottom bias power less than about 50 W/cm².

8. The method of claim 1, wherein laterally trimming the one of the second source/drain regions is performed by introducing an oxygen precursor at a flow rate lower than a flow rate of an oxygen precursor used in etching the one of the second source/drain regions.

9. The method of claim 1, wherein laterally trimming the one of the second source/drain regions is performed by introducing an oxygen-free precursor on the one of the second source/drain regions.

10. The method of claim 1, wherein etching the one of the second source/drain regions and laterally trimming the one of the second source/drain regions are in-situ performed.

11. A method, comprising:
forming a first semiconductive nanostructure, and a second semiconductive nanostructure vertically arranged with respect to the first semiconductive nanostructure;
forming a plurality of first epitaxial structures on opposite sides of the first semiconductive nanostructure, and a plurality of second epitaxial structures on opposite sides of the second semiconductive nanostructure;
forming a dielectric layer over the second epitaxial structures;
forming a first gate wrapping around the first semiconductive nanostructure, and a second gate wrapping around the second semiconductive nanostructure;
etching through the dielectric layer and one of the second epitaxial structures to form an opening exposing the one of the first epitaxial structures;
etching a sidewall of the one of the second epitaxial structures to create an offset from a sidewall of the dielectric layer within the opening;
after creating the offset from the sidewall of the dielectric layer within the opening, forming a silicide on the sidewall of the one of the second epitaxial structures; and
filling a contact material in the opening.

12. The method of claim 11, wherein the silicide is in contact with a bottom surface of the dielectric layer exposed from the one of the second epitaxial structures.

13. The method of claim 11, wherein the contact material is in contact with a bottom surface of the dielectric layer exposed from the one of the second epitaxial structures.

14. The method of claim 11, wherein creating the offset from the sidewall of the dielectric layer within the opening is performed ex-situ with etching through the dielectric layer and the one of the second epitaxial structures.

15. The method of claim 11, wherein creating the offset from the sidewall of the dielectric layer within the opening is performed by a dry etching process without a bias power.

16. A semiconductor structure, comprising:
a first transistor comprising:
first semiconductor sheets;
a first gate structure surrounding each of the first semiconductor sheets; and
first source/drain structures on either side of each of the first semiconductor sheets;
a second transistor over the first transistor, the second transistor comprising:
second semiconductor sheets;
a second gate structure surrounding each of the second semiconductor sheets; and
second source/drain structures on either side of each of the second semiconductor sheets; and
a source/drain contact extending through one of the second source/drain structures of the second transistor to one of the first source/drain structures of the first transistor, the source/drain contact comprising:
a first profile having a first sidewall and a second sidewall opposing the first sidewall; and
a second profile over the first profile and having a third sidewall and a fourth sidewall opposing the third sidewall, wherein at a boundary of the first profile and the second profile, a width between the third sidewall and the fourth sidewall is greater than a width between the first sidewall and the second sidewall by a non-zero offset value.

17. The semiconductor structure of claim 16, further comprising a silicide layer interfacing the second profile of the source/drain contact.

18. The semiconductor structure of claim 17, wherein the silicide layer is spaced apart from the first profile of the source/drain contact.

19. The semiconductor structure of claim 16, wherein the source/drain contact further comprises a third profile over the second profile and having a fifth side wall and a sixth sidewall opposing the fifth sidewall, and wherein at a boundary of the third profile and the second profile, a width between the fifth sidewall and the sixth sidewall is less than the width between the third sidewall and the fourth sidewall.

20. The semiconductor structure of claim 16, wherein along a vertical direction, a variation in the width between the first sidewall and the second sidewall of the first profile is different from a variation in the width between the third sidewall and the fourth sidewall of the second profile.
